(19) United States
(12) Patent Application Publication
(10) Pub. No.: US 2013/0316546 A1
(43) Pub. Date: Nov. 28, 2013

(54) METHODS OF ATOMIC LAYER DEPOSITION OF HAFNIUM OXIDE AS GATE DIELECTRICS

(71) Applicant: Jinhong Tong, Santa Clara, CA (US)

(72) Inventor: Jinhong Tong, Santa Clara, CA (US)

(73) Assignee: Intermolecular, Inc., San Joe, CA (US)

(21) Appl. No.: 13/480,203

(22) Filed: May 24, 2012

(51) Int. Cl. H01L 21/314

(52) U.S. Cl. 438/785; 257/E21.266

(57) ABSTRACT

In some embodiments, the present invention discloses a two-step deposition process for forming hafnium oxide gate dielectric, comprising an interface layer deposition followed by a bulk layer deposition. In the interface layer deposition process, water is used as an oxidizer precursor together with a hafnium-containing precursor. In the bulk layer deposition process, oxygen or ozone is used as an oxidizer precursor together with a hafnium-containing precursor.

### TECHNICAL FIELD

This invention relates generally to semiconductor devices and, more particularly, to methods for forming gate dielectrics and devices formed by the methods.

### BACKGROUND OF THE INVENTION

As integrated circuit feature sizes decrease, other device dimensions also decrease to maintain the proper device operation. For example, as gate conductor widths decrease, the thickness of the gate dielectric needs to decrease to provide proper capacitance to control the transistor.

To meet the requirements of sub-100 nm devices, an equivalent oxide thickness (EOT) of less than 1.5 nm is needed. Using SiO₂ as the gate dielectric, it is difficult to maintain its dielectric property below about 2 nm thickness due to the high tunneling leakage.

High-k materials, i.e., dielectric materials having a dielectric constant (k) greater than that of SiO₂ (k˜3.9), can provide high capacitance even for thicker structures, and thus have been studied as replacement for SiO₂. For example, a k value of 20, which can be obtained with various transition metal oxides such as hafnium oxide, can be formed into structures that are about five times thicker than conventional SiO₂ films without sacrificing capacitance characteristics of the resulting device. The thicker gate dielectric layer of high-k material can reduce tunneling leakage current through the gate, enabling sub-100 nm MOSFET devices.

The fabrication of high-k gate dielectric layers can provide difficulty in realizing the full benefits of the high dielectric constant. For example, processing high-k dielectric layers in the presence of oxygen at elevated temperatures, e.g., high-k deposition or subsequent anneal processes, can form a SiO₂ interfacial layer between the silicon substrate and the high-k layer. The SiO₂ interfacial layer can increase the effective oxide thickness, reducing the capacitance of the gate dielectric layer. Further, high-k gate dielectrics can contain a greater number of bulk traps and interface traps than thermally growth SiO₂ gate dielectrics. The traps can degrade the device performance, such as sub-threshold slope, threshold voltage, flatband voltage shift, and Frenkel-Poole tunneling leakage.

Thus there is a need to develop improved methods and structures involving high-k gate dielectrics and related semiconductor devices.

### SUMMARY OF THE DISCLOSURE

In some embodiments, methods to form a gate dielectric with improved electrical properties are provided. The gate dielectric can include hafnium oxide, hafnium silicon oxide, zirconium oxide, or other high-k dielectrics. In some embodiments, the methods involve forming a bulk hafnium oxide with low defect density on an interfacial layer of hafnium oxide with improved interface trap charge density. This hafnium oxide layer can be used as a high k gate dielectric with improved electrical properties such as low leakage current density at small thicknesses.

In some embodiments, provided is a two-step deposition process including an interface layer deposition followed by a bulk layer deposition. In the interface layer deposition process, water is used as an oxidizer precursor together with a hafnium-containing precursor to deposit an interface layer of hafnium oxide. Hafnium oxide layer deposited using water oxidizer can have less silicon oxide formation at the interface with a silicon substrate, leading to lower effective oxide thickness. In the bulk layer deposition process, oxygen or ozone is used as an oxidizer precursor together with a hafnium-containing precursor to deposit a bulk layer of hafnium oxide. Hafnium oxide layer deposited using oxygen or ozone oxidizer can be denser with fewer defects, such as OH− or H+ residue ion defects.

In some embodiments, provided is an atomic layer deposition (ALD) process including an interface layer deposition followed by a bulk layer deposition. In some embodiments, an ALD process is provided, including depositing a hafnium oxide layer by a first number of cycles using water and a hafnium containing precursor, such as HCl₄, followed by a second number of cycles using oxygen or ozone and the hafnium containing precursor. Fewer defects, e.g., OH− defects, and less oxygen diffusion to the silicon interface can provide a hafnium oxide layer with improved electrical properties, suitable for high k gate dielectrics in semiconductor device applications.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates an illustrative metal-oxide semiconductor field effect transistor (MOSFET) device according to some embodiments of the present invention.

FIGS. 2A-2B illustrate a fabrication sequence for an exemplary metal gate electrode according to some embodiments of the present invention.

FIG. 3 illustrates a flow chart of an ALD deposition of metal oxide dielectric materials according to some embodiments of the present invention.

FIGS. 4A-4F illustrate an exemplary process flow schematic of an ALD deposition of an exemplary hafnium oxide according to some embodiments of the present invention.

FIG. 5 illustrates an exemplary hafnium oxide gate dielectric according to some embodiments of the present invention.

FIG. 6 illustrates an exemplary flowchart for forming a hafnium oxide gate dielectric layer according to some embodiments of the present invention.

FIG. 7 illustrates an exemplary flowchart for forming a semiconductor device according to some embodiments of the present invention.

### DETAILED DESCRIPTION OF THE PREFERRED EMBODIMENTS

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, methods, and structures fabricated from the methods, are provided to form a gate dielectric, for example, hafnium oxide, hafnium silicon oxide (HfSiOₓ), zirconium oxide, or other high k dielectrics. In the following description, hafnium oxide is used as an illustrative example, but other high k dielectrics can be used instead or in addition to hafnium oxide. For example, derivatives of hafnium oxide such as hafnium silicon oxide (HfSiOₓ) or hafnium aluminum oxide (HfAlOₓ), or high k dielectrics having similar behaviors as compared to hafnium oxide such as zirconium oxide may be used.

The hafnium oxide gate dielectric can include a bulk hafnium oxide having a low defect density. The bulk hafnium oxide may be positioned on an interfacial layer of hafnium oxide having an improved interface trap charge density. In addition, the interface hafnium oxide can reduce the formation of interface SiO₂, reducing the equivalent oxide thickness of the gate dielectric.

In some embodiments, the hafnium oxide gate dielectric can be formed by a two-step deposition process, which includes an interface layer deposition followed by a bulk layer deposition. In the interface layer deposition process, water is used as an oxidizer precursor. A hafnium oxide layer deposited using the water oxidizer, in some cases, can be expected to have fewer interface traps. The process also results in less silicon oxide formation at the interface with a silicon substrate and leads to an improved interface trap density and lower effective oxide thickness. In the bulk layer deposition process, oxygen and/or ozone is used as an oxidizer precursor. A hafnium oxide layer deposited using oxygen or ozone oxidizer can be denser and can have fewer defects, such as OH− or H+ residue ion defects.

Advances in semiconductor processing have demanded ever-increasing high functional density with continuous size scaling. This scaling process has led to the adoption of high-k gate dielectrics and metal gate electrodes in metal gate stacks in semiconductor devices.

High-k gate dielectrics can offer a way to scale down the thickness of the gate dielectric and still maintain the acceptable gate leakage current. The use of high-k gate dielectrics is often accompanied by a metal gate electrode, since thin gate dielectric layers may cause poly depletion, affecting the device operation and performance. Metal gate electrodes further have an advantage of higher electrical conductance, as compared to poly gates, and thus can improve signal propagation times.

The manufacture of high-k dielectric devices entails the integration and sequencing of many unit processing steps, with potential new process developments, since in general, high-k gate dielectrics are much more sensitive to process conditions than silicon dioxide. For example, interface traps and interface oxide formation can adversely affect the performance of the high-k gate structures.

Industry continues to search for new dielectric materials that exhibit high k value (i.e., dielectric constant) and low leakage, to allow for further miniaturization of electronic devices. These materials may be used as the dielectric layer in electronic components such as capacitors, memory cell structures, and other devices. The k value is a measure of the polarization capability of dielectric materials in response to external electrical field, which can be used to store charges in capacitors. The ability of a dielectric material to store charge is also conveniently represented by the equivalent oxide thickness (“EOT”). A low EOT implies an increased ability to miniaturize semiconductor devices. The leakage is a measure of the capacitor's capability to retain stored charge for a certain period of time. Both EOT and leakage are important parameters for the miniaturization of electronic components such as capacitors, memory cell structure and other devices. Typical high-k materials include Al₂O₃ (k^{˜}9), HfSiO (k^{˜}5-20), ZrO₂ (k^{˜}25), HfO₂ (k^{˜}25), Ta₂O₅ (k^{˜}26), and TiO₂ (k^{˜}80).

In some embodiments, the hafnium oxide gate dielectric layers can replace SiO₂ gate dielectric with thinner equivalent oxide thickness (EOT) required for lower transistor operating voltages and smaller transistor dimensions. Further, the hafnium oxide layer can have a minimum SiO₂ interfacial layer. During the formation of hafnium oxide on a silicon layer, an interface layer of SiO₂ could be formed in addition to the hafnium oxide, resulting in two layers in series with each other. The two-layer equivalent oxide thickness would much higher than that of the hafnium oxide layer alone, and depending on the thickness of the SiO₂ interfacial layer, can be determined or limited by the SiO₂ interfacial layer thickness.

In some embodiments, provided is a two-step deposition process to form a hafnium oxide layer, including depositing a limited oxygen reactive layer of hafnium oxide before depositing a high quality hafnium oxide. The present two step deposition process can provide a hafnium oxide layer with minimum SiO₂ formation, and a high quality interface to maintain high channel carrier mobility for the semiconductor device.

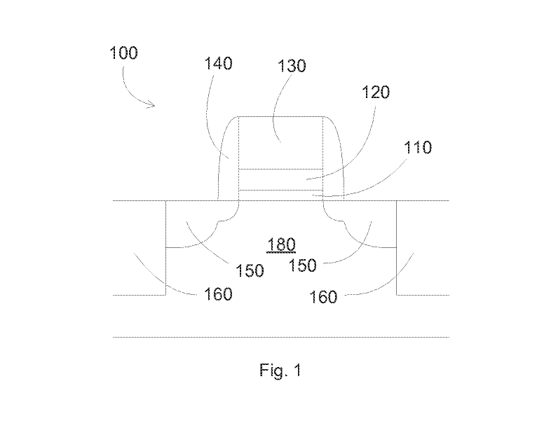

FIG. 1 illustrates an illustrative metal-oxide semiconductor field effect transistor (MOSFET) device according to some embodiments of the present invention. The device 100 can be incorporated into integrated circuits, which can also include various interconnects for connecting multiples devices including the device 100. The device 100 may include a substrate 180, which may be made from single crystal silicon. Other substrate materials include silicon-germanium. A gate stack may be fabricated on the substrate 180. The gate stack is shown to include a high-k gate dielectric layer 110, gate electrode layer 120 provided over the gate dielectric layer 110, and gate conductor layer 130 provided over the gate electrode layer 120. The gate electrode layer 120 can be a polysilicon gate layer or a metal gate layer. The device 100 is isolated from other devices by isolation regions 160, such as shallow trench isolation or local oxidation of silicon (LOCOS) isolation. The device 100 also includes spacers 140 and source and drain regions 150. The source and drain regions 150 are doped, for example, with arsenic, phosphorous, boron or other suitable materials, which are selected based on the desired transistor characteristics, using a self-aligning ion implantation process in substrate 180 or other suitable process. Other components can be included, such as n-well or p-well region, depending on the type of the semiconductor device.

The gate electrode layer 120 is deposited on the high-k dielectric layer 110 and includes aluminum, polysilicon, or other suitable conductive materials (e.g., TiN, TaN, HfN, RuN, WN, W, MoN, TaSiN, RuSiN, WSiN, HfSiN, TiSiN, etc). The spacers 140 are deposited on the sides of gate electrode layer 120, high-k dielectric layer 110, and can include SiO₂, Si₃N₄, TEOS or other suitable dielectric material. The spacers 140 isolate the gate electrode 120 and high-k dielectric layer 110 from the source and drain regions 150.

The high-k dielectric layer 110 may include a high-k dielectric material of HfO₂. The high-k dielectric layer 110 provides an equivalent oxide thickness (EOT) that allows increased performance and reduced transistor device size as compared to silicon oxide dielectric while not increasing tunneling leakage current through the gate.

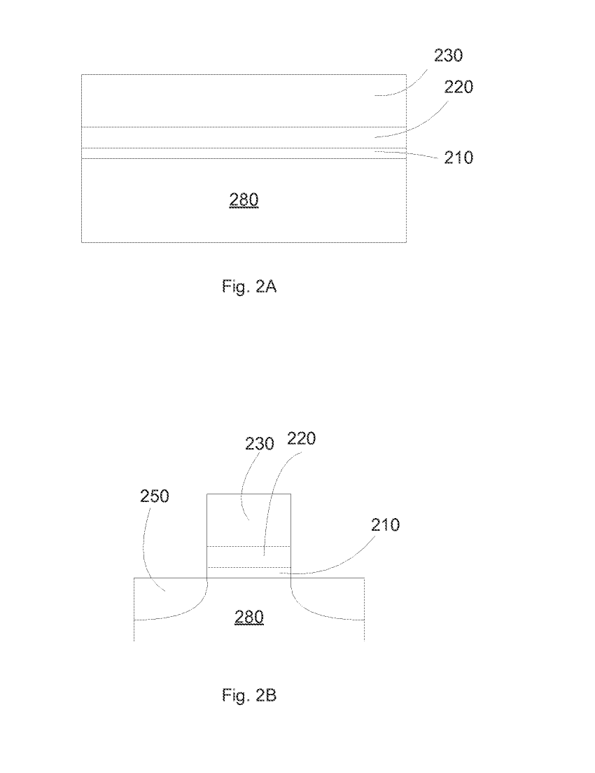

FIGS. 2A-2B illustrate a fabrication sequence for a metal gate electrode according to some embodiments of the present invention. In FIG. 2A, blanket layers of gate dielectric 210, metal gate layer 220 and gate conductor layer 230 are deposited on a substrate 280. The substrate 280 can be previously processed, for example, to form a device well and isolation regions. FIG. 2A illustrates just one example of the structure. Other configurations can be used, such as a single metal gate layer instead of a metal gate layer 220 and a gate conductor layer 230, and a gate dielectric layer stack comprising a high-k dielectric layer on a silicon dioxide pedestal layer instead of a single gate dielectric layer 210.

The gate dielectric layer 210 can be formed of hafnium oxide using two step deposition with water and oxygen or ozone as an oxidant. The hafnium oxide gate dielectric can improve the performance characteristics of semiconductor devices. In some embodiments, the thickness of the gate dielectric is less than about 10 nm or, more specifically, less than about 5 nm. The gate dielectric layer 210 can be formed by various deposition techniques, such as an ALD process.

Disposed on the gate dielectric layer 210 is a metal gate layer 220 together with a gate conductor layer 230. Alternatively, the gate conductor layer 230 can be omitted, leaving only a metal gate layer 220. The metal gate layer 220 typically includes a first metal, and the gate conductor 230 can either include a poly silicon or a second metal, different from the first metal. In some embodiments, the metal gate layer 220 is a metal-containing layer, having a metal component together with other combination of materials.

The metal gate layer 220 can include a refractory metal or a nitride of a refractory metal, such as titanium nitride. Alternatively, the metal gate layer 220 can include other metals, such as WN, TaN, Mo, RuO₂, or NiSi. The thickness of the metal gate layer 220 can be less than about 20 nm with the gate conductor layer, or can be less than about 200 nm without a gate conductor layer.

The gate conductor layer 230 can include silicon, such as doped poly silicon or amorphous silicon. Alternatively, the gate conductor layer 230 can include a second metal, different from the first metal in the metal gate layer 220. In addition, the gate conductor can be omitted. The thickness of the gate conductor can be less than 200 nm.

The metal gate layer 220 and gate conductor layer 230 can be formed by any methods, such as atomic layer deposition (ALD), physical vapor deposition (PVD), chemical vapor deposition (CVD), and spin coating.

FIG. 2B shows a patterning for the gate conductor layer 230, the metal gate 220, and the gate dielectric 210. Any patterning process can be used, for example, lithography patterning process using photoresist mask and dry or wet etching. The layers can be patterned using a plasma etch process or a wet etch process.

After the completion of the metal gate electrode, the substrate can be further processed to form active devices and circuits. For example, additional steps of implanting dopants to form source and drain structures 250, forming gate spacers 240, and shallow junctions. Interconnect metal lines can be included, connecting a plurality of active devices to form an integrated circuit. There can be silicide regions (not shown) on the gate conductor layer 230 for improving contact resistance. The device shown is an exemplary planar device configuration, and other device configurations are also within the scope of the present invention, such as tri-gate transistor configurations, fin-FET configurations, or different types of transistors or devices.

In some embodiments, an ALD (atomic layer deposition) process involving an interface layer deposition followed by a bulk layer deposition is provided. In some embodiments, an ALD process involving depositing a hafnium oxide layer by a first number of cycles using water and a hafnium containing precursor, such as HfCl₄, followed by a second number of cycles using oxygen or ozone and the hafnium containing precursor, is provided. Fewer defects, e.g., OH− defects, and less oxygen diffusion to the silicon interface can provide a hafnium oxide layer with improved electrical properties, suitable for high k gate dielectrics in semiconductor device applications.

ALD as used herein refers to the sequential introduction of two or more reactive compounds to deposit a layer of material on a substrate surface. The two, three or more reactive compounds may alternatively be introduced into a reaction zone of a deposition chamber. Usually, each reactive compound is separated by a time delay to allow each compound to adhere and/or react on the substrate surface. In some embodiments, a first precursor or compound A is pulsed into the reaction zone of a deposition chamber (e.g., ALD chamber) followed by a first time delay. Next, a second precursor or compound B is pulsed into the reaction zone followed by a second delay. During each time delay a purge gas, such as argon or nitrogen, may be pulsed or otherwise provided into the deposition chamber to purge the reaction zone or otherwise remove any residual reactive compound or by-products from the reaction zone or other surfaces. Alternatively, the purge gas may flow continuously throughout the deposition process. The reactive compounds are alternatively pulsed until a desired film or film thickness is formed on the substrate or deposition. In either scenario of a continuous or intermittent purge gas flow, the ALD process of pulsing compound A, purge gas, pulsing compound B, and purge gas is an ALD cycle. An ALD cycle can start with either compound A or compound B and continue the respective order of the ALD cycle until achieving a film with the desired thickness. In some embodiments, a first precursor or compound A is pulsed into the reaction zone of a deposition chamber (e.g., ALD chamber) followed by a first time delay. Next, a second precursor or compound B is pulsed into the reaction zone followed by a second delay. Next, a third precursor or compound C is pulsed into the reaction zone followed by a third delay. During each time delay a purge gas, such as argon or nitrogen, may be pulsed or otherwise provided into the deposition chamber to purge the reaction zone or otherwise remove any residual reactive compound or by-products from the reaction zone or other surfaces. Alternatively, the purge gas may flow continuously throughout the deposition process so that only the purge gas flows during the time delay between pulses of reactive compounds. The reactive compounds are alternatively pulsed until a desired film or film thickness is formed on the substrate or deposition surface. In either scenario of a continuous or intermittent purge gas flow, the ALD process of pulsing compound A, purge gas, pulsing compound B, purge gas, pulsing compound C, and purge gas is an ALD cycle. Alternatively, the ALD process of pulsing compound A, purge gas, pulsing compound B, purge gas, pulsing compound C, purge gas, pulsing compound B, and purge gas is an ALD cycle. An ALD cycle can start with either compound A, compound B, or compound C and continue the respective order of the ALD cycle until achieving a film with the desired thickness.

A “pulse” as used herein is intended to refer to a quantity of a particular compound that is intermittently or non-continuously introduced into a reaction zone of a processing chamber. The quantity of a particular compound within each pulse may vary over time, depending on the duration of the pulse. The duration of each pulse is variable depending upon a number of factors such as, for example, the volume capacity of the deposition chamber employed, the vacuum system coupled thereto, and the volatility/reactivity of the particular compound itself. A “half-reaction” as used herein is intended to refer to a pulse of precursor step followed by a purge step.

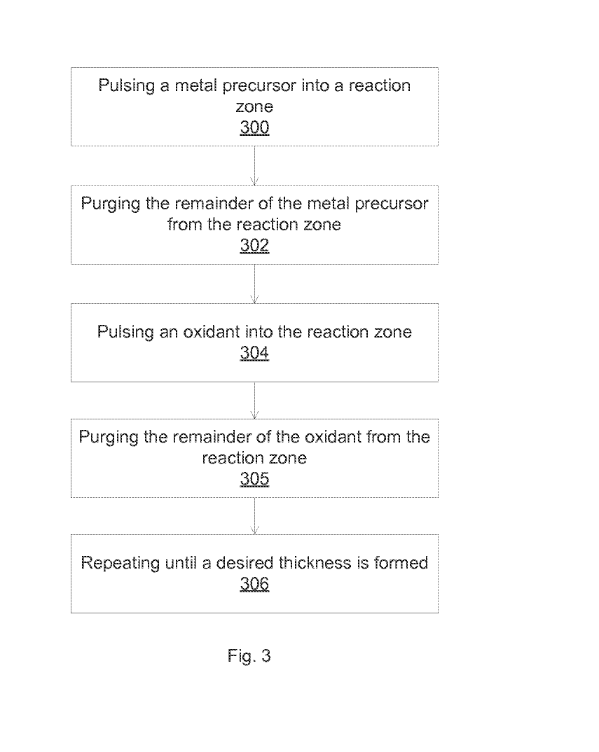

FIG. 3 illustrates a flow chart of an ALD deposition of metal oxide dielectric materials according to some embodiments of the present invention. In step 300, a metal precursor is pulsed into the reaction zone. A portion of the precursor adsorbs onto the surface at reactive sites. In step 302, the remainder of the precursor is purged from the reaction zone. In step 304, an oxidant is then pulsed into the reaction zone to react with the adsorbed precursor and form a metal oxide dielectric material. In step 305, the remainder of the oxidant is purged from the reaction zone. In step 306, this sequence is repeated until the desired thickness of the metal oxide dielectric material is formed.

In some embodiments, methods for forming the hafnium oxide gate dielectric layers using ALD are provided. Some of the materials and/or layers of the hafnium oxide layer may be deposited or otherwise formed using a variety of deposition techniques, but in many embodiments described herein, all of the materials and/or layers of hafnium oxide layer may be deposited using thermal ALD processes and/or plasma-enhanced ALD (PE-ALD). In some embodiment, an interfacial hafnium oxide can be formed by utilizing a water (or OH−) based oxidizer agent, together with a bulk hafnium oxide formed by utilizing an oxygen based oxidizer agent, such as ozone, atomic oxygen, or oxygen plasma.

The ALD processes for depositing or otherwise forming hafnium oxide materials are typically conducted in a deposition chamber, such as an ALD chamber. The deposition chamber may maintain an internal pressure of less than about 760 Torr, such as within the range from about 10 mTorr to about 10 Torr or, more specifically, from about 100 mTorr to about 1 Torr, for example, about 350 mTorr. The temperature of the memory device, the substrate, or the substrate carrier/pedestal is usually maintained within the range from about 50° C. to about 1,000° C., such as from about 100° C. to about 500° C., such as from about 200° C. to about 400° C., or such as from about 250° C. to about 300° C.

The hafnium containing precursor can be pulsed, introduced, or otherwise provided into the deposition chamber at a flow rate within the range from about 0.1 sccm to about 200 sccm, such as from about 0.5 sccm to about 50 sccm, from about 1 sccm to about 30 sccm, for example, about 10 sccm. In general, flow rates depend on the size of the chamber and size of the substrate, and one having ordinary skill in the art would be able to scale these values up or down based on different sizes of chamber or substrates. The hafnium containing precursor can be provided along with a carrier gas, such as argon or nitrogen. The carrier gas may have a flow rate within the range from about 1 sccm to about 300 sccm, such as from about 2 sccm to about 80 sccm, from about 5 sccm to about 40 sccm, for example, about 20 sccm.

The hafnium containing precursor may be pulsed or otherwise provided into the deposition chamber at a rate within a range from about 0.01 seconds to about 60 seconds, for example, about 10 seconds, depending on the particular process conditions, hafnium containing precursor or desired composition of the deposited hafnium oxide material. In some embodiments, the hafnium containing precursor is a hafnium inorganic precursor, such as hafnium chloride (HfCl₄), hafnium iodine (Hfl₄), or anhydrous hafnium nitrate (Hf(NO₃)₄). In some embodiments, the hafnium containing precursor is a hafnium organic precursor including an organic ligand. For example, the metal source can be a hafnium containing precursor, which is a tetrakis(dialkylamino)hafnium compound, such as tetrakis(dimethylamino) hafnium ((Me₂N)₄Hf or TDMAH), tetrakis(diethylamino) hafnium ((Et₂N)₄Hf or TDEAH), or tetrakis(ethylmethylamino) hafnium ((EtMeN)₄Hf or TEMAH).

The hafnium containing precursor can be dispensed into a deposition chamber by introducing a carrier gas through an ampoule containing the hafnium organic precursor. An ampoule unit can include an ampoule, bubbler, canister, cartridge, or other container used for storing, containing, or dispersing chemical precursors. In another example, the ampoule can contain a liquid precursor (e.g., TDMAH or TDEAH) and be part of a liquid delivery system containing injector valve system used to vaporize the liquid precursor with a heated carrier gas. Generally, the ampoule can be heated to a temperature of about 180° C. or less, such as within a range from about 30° C. to about 90° C., for example, about 50° C. Alternatively, the hafnium containing precursor can be in gaseous form, such as HfCl₄, and can be delivered directly to the deposition.

The oxidizing agent (e.g., O₂, O₃, H₂O) may be pulsed, introduced, or otherwise provided into the deposition chamber at a flow rate within a range from about 0.01 seconds to about 60 seconds, depending on the particular process conditions, oxygen source gas or oxidizing agent or desired composition of the deposited metal oxide material. In one embodiment, such as for forming a metal-poor oxide material, the oxidizing agent may be pulsed, introduced, or otherwise provided into the deposition chamber at a rate within a range from about 0.001 seconds to about 1 second, such as from about 0.001 seconds to about 0.1 seconds, for example, about 0.05 seconds.

In some embodiments, the oxidizer for the interface hafnium oxide layer and the bulk hafnium oxide layer are different. For example, the oxidizer for the interface hafnium oxide layer can include a water or OH-based fluid, such as H₂O or H₂O₂ vapor. The oxidizer may be delivered to the process chamber by known methods. For example, a water vapor generator is used to generate water vapor and deliver (or pulse) it to the process chamber as the oxidizer.

The oxidizer for the bulk hafnium oxide layer can include an oxygen-based fluid, such as from an oxygen source that includes oxygen (O₂), atomic oxygen (O), ozone (O₃), derivatives thereof, plasmas thereof, or combinations thereof. Ozone may be formed inside or outside of the deposition chamber, such as the ALD chamber. In some embodiments, the oxidizing agent contains ozone formed by an ozone generator positioned outside of the deposition chamber. Ozone is generated and then flowed or directed into the deposition chamber and exposed along with the metal source gas to the substrate surface. In some embodiments, the oxidizing agent contains ozone formed by a plasma generated within the interior of the deposition chamber. Oxygen gas flowed or directed into the deposition chamber, then ignited or formed into ozone and/or atomic oxygen before being sequentially exposed along with the hafnium containing precursor to the substrate surface.

The chamber may be purged between oxidizing and precursor exposure, and between repeating cycles of exposure to the oxidizer and precursor, and the cycles may be repeated a desired number of times. The purging process may use an inert gas, for example, such as N₂, H₂ or Ar. The purge time may be any desired time for removing excess reactant from the chamber.

A carrier gas or a purge gas can be provided at the same time as the hafnium containing precursor and/or the oxidant precursor, but can be also provided between the pulses of the hafnium containing precursor and/or the oxidant precursor. The carrier gas or purge gas can flow continuously during the ALD process or can be intermediately and/or sequentially pulsed, introduced, or otherwise provided during the ALD process. The carrier gas or purge gas may be pulsed, introduced, or otherwise provided into the deposition chamber at a rate within a range from about 1 second to about 60 seconds, depending on the particular process conditions, source gases, or desired composition of the deposited metal oxide material. In some embodiments, the carrier gas or a purge gas may be pulsed, introduced, or otherwise provided into the deposition chamber at a rate within a range from about 1 second to about 60 seconds, such as from about 2 seconds to about 20 seconds, for example, about 10 seconds or about 15 seconds. Other purging times can be used.

The carrier gas or purge gas may contain nitrogen, argon, helium, hydrogen, a forming gas, mixtures thereof, or combinations thereof. The carrier gas or the purge gas may be sequentially pulsed, introduced, or otherwise provided after each pulse of the hafnium containing precursor and each pulse of the oxidizing agent during the ALD cycle. The pulses of purge gas or carrier gas are typically pulsed, introduced, or otherwise provided at a flow rate within a range from about 2 standard liters per minute (slm) to about 22 slm, such as about 10 slm. Other purging flows can be used, such as He or Xe.

Once the desired number of cycles of alternating exposure to the oxidizer and precursor are carried out, a post-deposition anneal may be performed to densify the film stack. The post-deposition anneal may be a high temperature bake, a post-oxidation anneal, or a high temperature anneal in the presence of a non-oxidizing gas, such as N₂. In some embodiments, the substrate temperature during the post-deposition anneal is in the range of about 500-1000° C., such as about 550-800° C. Exemplary post-deposition anneals include exposure to NO at about 600° C. or exposure to N₂ at about 800° C. The anneal may be performed for any desired amount of time. By way of example and not limitation, the anneal may be performed for about 30 seconds up to 30 minutes, or about 5-20 minutes, for example about 10 minutes. In some embodiments, a low temperature post-deposition anneal may be carried out, for example at a temperature below about 500° C., such as about 250-450° C. In some embodiments, a flow rate of up to about 20 slm, for example about 0.1-5 slm, may be used for the oxidation gas or non-oxidizing gas.

In some embodiments, a gate dielectric layer can be formed using a hafnium oxide layer. The hafnium containing precursor can comprise a hafnium containing precursor of hafnium tetrachloride (HfCl₄). The oxidant can comprise water, oxygen or ozone. The deposition temperature can be from 50 to 250° C.

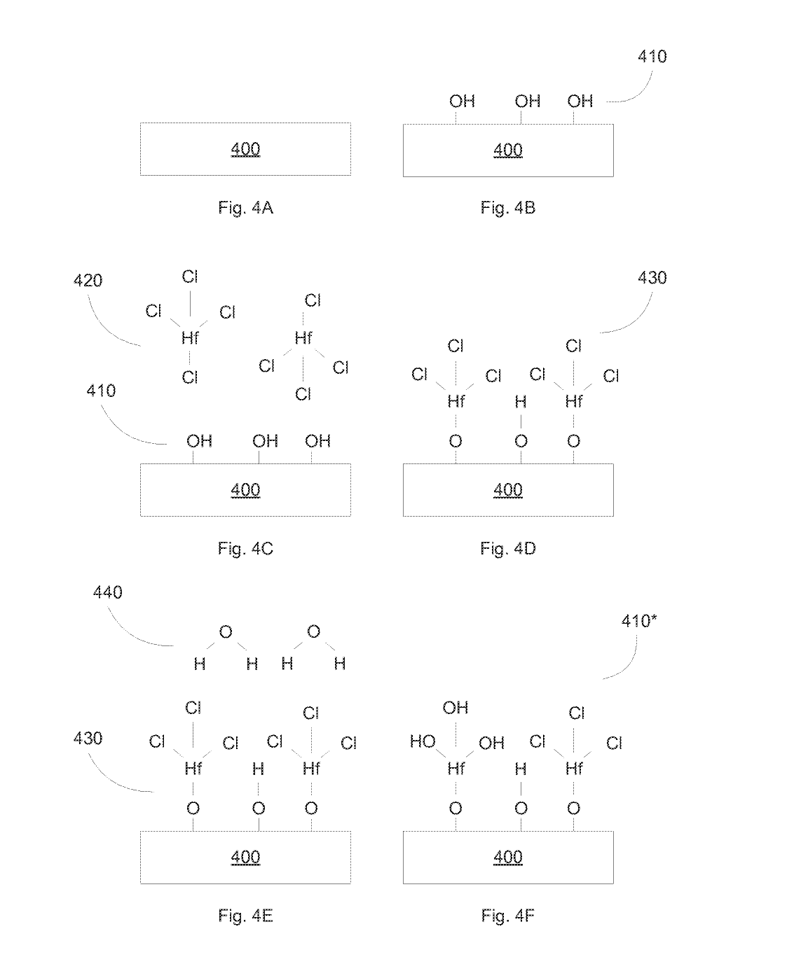

FIGS. 4A-4F illustrate an exemplary process flow schematic of an ALD deposition of an exemplary hafnium oxide according to some embodiments of the present invention. In FIG. 4A, a substrate 400 is provided in a process chamber. The substrate can be a semiconductor substrate such as a silicon substrate. In some embodiments, the substrate 400 is already processed to form appropriate structures for semiconductor devices. For example, n well and p well regions can be formed for forming a foundation for p-type and n-type transistors. In FIG. 4B, the substrate surface is conditioned for ALD deposition, for example, by providing an OH terminated surface 410. The OH surface 410 can be prepared by exposing the substrate to water.

In FIG. 4C, hafnium chloride (HfCl₄) precursor 420 is introduced to the process chamber. In FIG. 4D, hafnium chloride precursor reacts with the OH surface to form hafnium oxide bonding 430. The un-reacted hafnium chloride precursor is purged from the chamber. In FIG. 4E, water 440 is introduced to the process chamber. In FIG. 4F, water molecules react with hafnium surface 430 to conditioning the substrate surface to OH terminated surface 410*. The process cycle continues, for example, by introducing hafnium chloride precursor to react with OH terminated surface.

In some embodiments, provided is forming an interface hafnium oxide layer on a silicon substrate. The interface hafnium oxide can be formed by reacting a hafnium containing precursor, such as hafnium tetrachloride with a water (or OH−) based oxidant. The use of water based oxidant can reduce the oxidation of the silicon substrate, limiting or eliminating the formation of interface SiO₂ layer. In addition, water based oxidant in an ALD deposition process of hafnium oxide can be expected to reduce interface trap density, resulting in better gate dielectric behavior in a semiconductor device. For example, during a number of first ALD cycles of ALD hafnium oxide deposition, a water based oxidant step can be provided to engineer the interface of the hafnium oxide with the silicon substrate. The water based oxidant step can include water or OH-containing oxidant such as alcohol. The engineered interface can reduce oxidation of the silicon surface or can reduce interface traps at the silicon interface.

For example, for ALD reaction using HfCl₄ precursor and H₂O oxidant, the water vapor pressure, water pulse time and purge time can be optimized to get a lower defect hafnium oxide layer. For example, by pulsing water in longer time can improve the surface OH− density to achieve a better quality film. Or by increasing the water purging time, there is no water residues remaining in the reaction chamber, resulting in fewer OH− defects incorporated into the hafnium oxide layer.

A bulk hafnium oxide layer then can be formed on the interface hafnium oxide layer, by reacting a hafnium containing precursor (for example, the same hafnium containing precursor may be used to form the interface hafnium oxide layer) with an oxygen based oxidant, such as ozone, atomic oxygen or plasma excited oxygen. The used of oxygen based oxidant can provide a dense hafnium oxide layer with fewer defects. For example, for ALD reaction using HfCl₄ precursor and O₃ oxidant, the flow rate and concentration of ozone can be optimized to achieve hafnium oxide layer with good electrical performance. For example, low concentration and low flow of ozone can be used, followed by high concentration and high flow to obtain less ozone diffusion to the interface with high oxygen concentration in the bulk hafnium oxide layer.

In some embodiments, a method to form a hafnium oxide gate dielectric for a semiconductor device is provided. The method includes providing a silicon-containing substrate; depositing an interface layer of hafnium oxide on the substrate using an ALD process involving alternating a hafnium-containing precursor and a water or OH− containing precursor; and depositing a bulk layer of hafnium oxide on the interface layer using an ALD process comprising alternating the hafnium-containing precursor and an oxygen-containing precursor or a plasma oxygen precursor. The ALD process for depositing the interface layer can have between about 5 to 20 ALD cycles, or for depositing a layer having less than 3 monolayer thickness or less than about 1 nm thickness. The ALD process for depositing the bulk layer can have between 5 to 40 ALD cycles, or for less than 10 monolayer thickness, or for less than about 2 nm thickness.

In some embodiments, provided are methods to form a gate dielectric, including depositing a first layer of hafnium oxide by an ALD process that uses a hafnium containing precursor and a water or OH-containing liquid vapor, followed depositing a second layer of hafnium oxide by an ALD process that uses the hafnium containing precursor and an oxygen or ozone-containing gas.

In some embodiments, provided is an ALD process to form a gate dielectric, including depositing a first number of cycles with a hafnium containing precursor and a water or OH-containing liquid vapor, followed by a second number of cycles with the hafnium containing precursor and an oxygen or ozone-containing gas.

In some embodiments, provided are methods to form a semiconductor device, including forming a hafnium oxide gate dielectric on a semiconductor substrate, followed by forming a transistor structure on the hafnium gate dielectric. The hafnium gate dielectric can be formed by a two-step ALD deposition process, including a first step of using a hafnium containing precursor and a water-based oxidant and a second step of using the hafnium containing precursor and an oxygen-based oxidant.

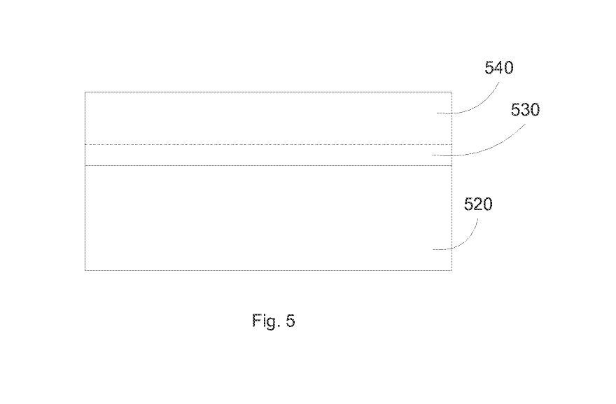

FIG. 5 illustrates an exemplary hafnium oxide gate dielectric according to some embodiments of the present invention. A second hafnium oxide layer 540 is formed on a first hafnium oxide layer 530, which is formed on a silicon substrate 520. The formation of the first hafnium oxide layer 530 can be performed by a deposition by a first ALD process, utilizing a hafnium containing precursor and a water based oxidant. The formation of the second hafnium oxide layer 540 can be performed by a deposition by a second ALD process, utilizing the same hafnium containing precursor and an energetic oxygen based oxidant. In some embodiments, different hafnium containing precursors are used in the first and second ALD processes. In some embodiments, the two hafnium oxide layers are distinct, deposited in sequence. In some embodiments, the two hafnium oxide layers are deposited in situ, with the first layer immediately followed by the second layer, for example, by switching the oxidant from the water based to the energetic oxygen oxidant.

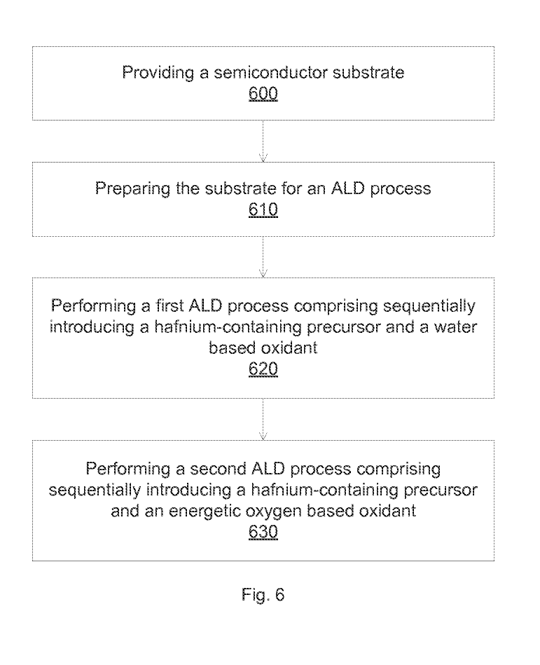

FIG. 6 illustrates an illustrative flowchart for forming a hafnium oxide gate dielectric layer according to some embodiments of the present invention. In operation 600, a semiconductor substrate is provided. The substrate can be a silicon substrate that can include one or more processing steps performed thereon.

In operation 610, the substrate is prepared for ALD process, For example, the substrate may be heated by employing a heated pedestal, on which the substrate is mounted in the ALD chamber. In this way, a pedestal temperature is maintained for an ALD deposition process so that the hafnium oxide layers can be deposited at this controlled temperature.

After preparing the substrate, a hafnium oxide layer is formed using an ALD process. In operation 620, a first few cycles of the ALD process, for example, between about 5 to 20 cycles, is used to form an interface hafnium oxide layer, For example, a hafnium containing precursor may be used together with a water based oxidant. In some embodiments, the water based oxidant can reduce the oxidation of the silicon substrate surface.

As mentioned above, ALD is a multi-step process used to deposit semiconductor layers. An ALD-deposited layer typically includes multiple cycles to deposit a layer of a desired thickness, so the process is repeated until the desired layer thickness has been deposited.

In a typical ALD metal oxide formation, a first reagent is provided to (e.g., flowed onto) a substrate by introducing the first reagent into an ALD chamber. The first reagent can be a hafnium-containing precursor that is used to form a hafnium oxide. For example, the first reagent can be a hafnium containing precursor such as tetrakis (diethylamido) hafnium (TDEAHf), tetrakis (dimethylamido) hafnium (TDMAHf), tetrakis (ethylmethylamido) hafnium (TEMAHf) or hafnium chloride (HfCl₄).

The excess (unreacted portion) of the first reagent is purged, for example by purging the ALD chamber to remove excess precursor. The purge duration can be less than or equal to about 60 seconds.

A second reagent is provided to the substrate. In some embodiments, the second reagent combines with the first reagent to form the hafnium oxide. The second reagent may be a water or OH based oxidizer, for example water vapor, or alcohol vapor. The second reagent forms an oxide of the metal contained in the first reagent (the precursor). The unreacted second reagent is then purged.

It is determined whether another ALD deposition cycle is to be performed. A typical ALD cycle may form a layer that is about 0.05 nm thick, for example. To form a 0.5 nm hafnium oxide layer, about 10 cycles may be needed to be performed. So, if it is determined that the desired number of cycles has been performed or that the desired thickness has been reached, the process continues. If more ALD cycles need to be completed, the sequence is repeated.

In operation 630, a bulk hafnium oxide layer is formed using ALD process with the hafnium containing precursor together with an energetic oxygen based oxidant, such as ozone or plasma oxygen. In some embodiments, the same first reagent of the hafnium-containing precursor is introduced to (e.g. flowed onto) a substrate by introducing the first reagent into the ALD chamber.

The excess (unreacted portion) of the first reagent is purged, for example by purging the ALD chamber to remove excess precursor.

A second reagent may be then provided to the substrate. The second reagent may be combined with the first reagent to form the bulk hafnium oxide. The second reagent is an energetic oxygen based oxidizer, for example ozone gas or plasma oxygen gas. The second reagent forms an oxide of the hafnium metal contained in the first reagent (the precursor). The unreacted second reagent is then purged.

It is determined whether another ALD deposition cycle is to be performed. A typical ALD cycle may form a layer that is 0.05 nm, for example. To form a 1 nm hafnium oxide layer, 20 cycles would need to be performed. So, if it is determined that the desired number of cycles has been performed or that the desired thickness has been reached, the process continues. If more ALD cycles need to be completed, the sequence is repeated.

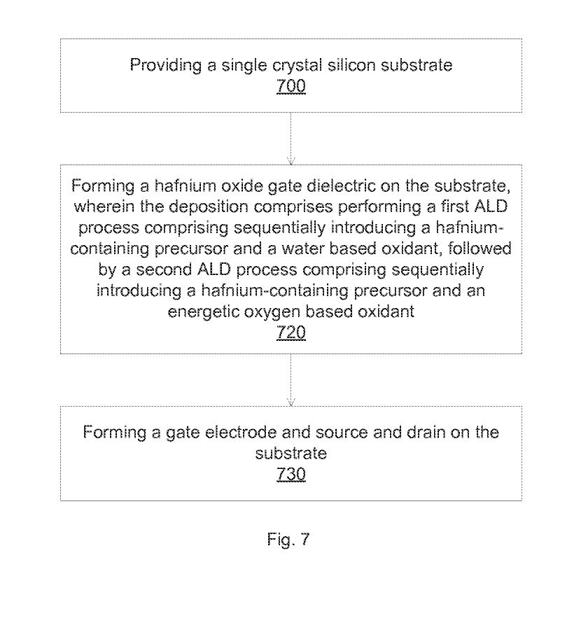

FIG. 7 illustrates an illustrative flowchart for forming a semiconductor device according to some embodiments of the present invention. The described flowchart is a general description of techniques used to form the semiconductor device described above. The flowchart describes techniques for forming a semiconductor device generally including a gate stack disposed on a semiconductor channel between a source and a drain. Although certain processing techniques and specifications are described, it is understood that various other techniques and modifications of the techniques described herein may also be used.

In operation 700, a silicon-containing substrate is provided. In operation 720, a hafnium oxide gate dielectric is formed on the substrate. The substrate is first prepared for the ALD process, for example, heated to a temperature less than or equal to about 450° C. After preparing the substrate, a hafnium oxide layer is formed using ALD process, including an interface hafnium oxide layer and a bulk hafnium oxide layer. A first few cycles of the ALD process, e.g., less than about 20 cycles, is used to form the interface hafnium oxide layer, utilizing a hafnium containing precursor together with a water or OH based oxidant.

The last cycles of the ALD process is used to form the bulk hafnium oxide layer, utilizing the hafnium containing precursor together with an energetic oxygen based oxidant. The ALD process can be a standard ALD process as discussed above, including sequentially introducing and purging the hafnium containing precursor and the oxidant to form the hafnium oxide layer.

In operation 730, other processes are performed to complete the semiconductor device, including depositing a gate electrode, a gate conductor, patterning the gate dielectric and the gate electrode and conductor, forming source and drain regions, and forming spacer. Device interconnection can also be included.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for forming a hafnium oxide layer, comprising
forming a first layer on a substrate, wherein the first layer comprises hafnium oxide, and wherein the first layer is formed by a combination of a hafnium containing precursor and water vapor; and
forming a second layer on the first layer, wherein the second layer comprises hafnium oxide, and wherein the second layer is formed by a combination of the hafnium containing precursor and one or more of oxygen molecules and ozone molecules.

2. A method as in claim 1 wherein a thickness of the first layer is less than about 1 nm.

3. A method as in claim 1 wherein the thickness of the second layer is less than about 2 nm.

4. A method as in claim 1 wherein the first and second layers are formed in situ in a same process chamber.

5. A method as in claim 1 wherein the second layer is formed by a combination of the hafnium containing precursor and ozone.

6. A method for forming a hafnium oxide layer, comprising
forming a first layer on a silicon-containing substrate, wherein the first layer comprises a hafnium oxide material deposited by a first ALD process, wherein the first ALD process comprises applying a hafnium-containing precursor followed by applying an OH-containing oxidant; and
forming a second layer on the first layer, wherein the second layer comprises a hafnium oxide material deposited by a second ALD process, wherein the second ALD process comprises applying the hafnium-containing precursor followed by applying an oxidant comprising oxygen gas or ozone gas.

7. A method as in claim 6 wherein the first ALD process for depositing the first layer comprises between about 5 to 10 ALD cycles.

8. A method as in claim 6 wherein the thickness of the first layer is less than about 1 nm.

9. A method as in claim 6 wherein the second ALD process for depositing the second layer comprises between about 5 to 20 ALD cycles.

10. A method as in claim 6 wherein the thickness of the second layer is less than about 2 nm.

11. A method as in claim 6 wherein the first and second layers are formed in situ in a same process chamber.

12. A method as in claim 6 wherein the second ALD process comprises applying an oxidant comprising ozone.

13. A method as in claim 6 further comprising
forming a semiconductor device on the hafnium oxide layer, wherein the hafnium oxide layer forms a gate dielectric layer of the semiconductor device.

14. A method for forming a semiconductor device, comprising
providing a silicon-containing substrate;
forming a gate dielectric layer on the substrate, wherein the gate dielectric layer comprises a hafnium oxide material deposited by
a first ALD process, wherein the first ALD process comprises applying a hafnium-containing precursor followed by applying an OH-containing oxidant, followed by
a second ALD process, wherein the second ALD process comprises applying the hafnium-containing precursor followed by applying an oxidant comprising oxygen gas or ozone gas; and
forming a gate electrode layer on the gate dielectric layer.

15. A method as in claim 14 wherein the first ALD process comprises between 5 to 10 ALD cycles.

16. A method as in claim 14 wherein the thickness of a layer deposited by the first ALD process is less than 1 nm.

17. A method as in claim 14 wherein the second ALD process comprises between about 5 to 20 ALD cycles.

18. A method as in claim 14 wherein the thickness of a layer deposited by the second ALD process is less than about 2 nm.

19. A method as in claim 14 wherein the second ALD process comprises applying an oxidant comprising ozone.

20. A method as in claim 14 further comprising
forming a source and drain regions on the substrate.
